(19) United States
(12) Patent Application Publication
(10) Pub. No.: US 2003/0138010 A1
(43) Pub. Date: Jul. 24, 2003

(54) Monolithically integrated switching circuit for regulating the luminous power of a laser diode

(76) Inventor: Manfred Herz, Mainz (DE)

Correspondence Address: DAVIDSON, DAVIDSON & KAPPEL, LLC, 485 SEVENTH AVENUE, 14TH FLOOR, NEW YORK, NY, 10018, US

(21) Appl. No.: 10/276,136

(22) PCT Filed: Apr. 20, 2001
(86) PCT No.: PCT/EP01/04488

(30) Foreign Application Priority Data
May 4, 2000 (DE) 20007884.4

(51) Int. Cl. H01S 3/00; H01S 5/00

(52) U.S. Cl. 372/38.02; 372/50

(57) ABSTRACT

The invention relates to a monolithic integrated circuit for controlling the light power of a laser diode optically coupled to at least one photodiode. Laser diodes are sensitive semiconductor components which can be destroyed in particular when current/voltage transients occur. It is an object of the invention, therefore to provide a monolithic integrated circuit for controlling the light power of a laser diode which can comprehensively protect a connected laser diode against destruction. To that end, the circuit has first terminals (40, 42, 44, 46, 48) for connecting at least one laser diode (50) and for connecting at least one photodiode (60) optically coupled thereto, an integrated device (90, 100) for controlling the control current of at least one connected laser diode (50), second terminals (20, 22) for applying a supply voltage, and an integrated device (150) connected to the second terminals and serving to suppress current and/or voltage transients.

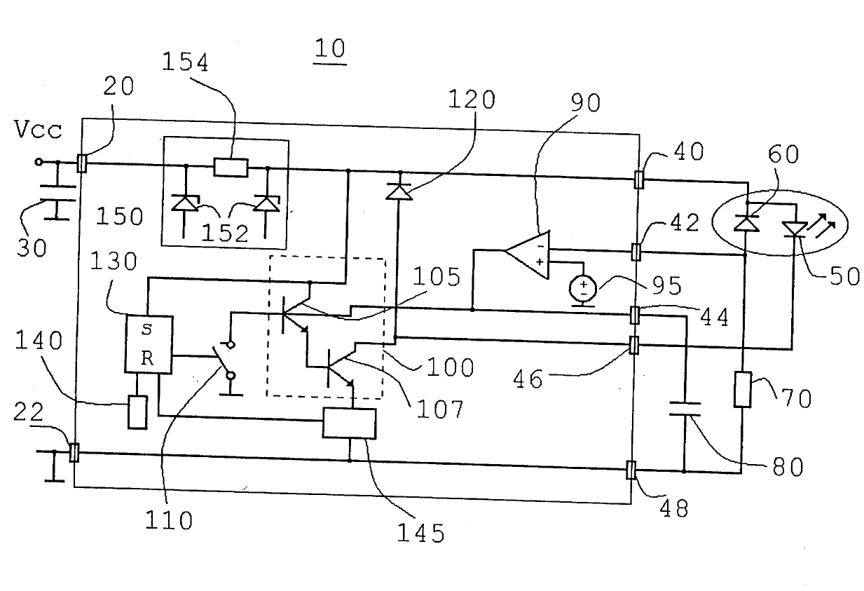

The invention relates to a monolithic integrated circuit for controlling the light power of a laser diode optically coupled to at least one photodiode.

Laser diodes are sensitive semiconductor components which can be destroyed in particular when current/voltage transients occur. Commercially available drivers for laser diodes are fabricated for example as integrated circuits which control the monitor current of a photodiode optically coupled to the laser diode, in order in this way to indirectly monitor the light power of the laser diode connected to the driver.

However, the commercially available laser diode drivers are unable to adequately protect connected laser diodes against current/voltage transients, against excessively high temperatures in the integrated circuit and against excessively high currents which are caused, for example, by damage to the laser diode or by an interruption of the feedback of the control loop of the integrated circuit.

Therefore, it is one object of the invention of providing a monolithic integrated circuit for controlling the light power of a laser diode which can comprehensively protect a connected laser diode against destruction.

The invention achieves this object firstly by means of the features of claim 1.

Accordingly, a monolithic integrated circuit is provided to which a laser diode/photodiode combination can be connected. The combination comprises a laser diode whose light power is to be controlled, and at least one photodiode which is optically coupled to the laser diode and monitors the light emitted by the laser diode. First terminals are provided for the connection of the laser diode, further terminals being provided for the connection of the at least one photodiode. Second terminals are provided, to which a supply voltage can be applied, which may supply for example a voltage in the range of 2.4 to 6 volts. Furthermore, the monolithic integrated circuit contains a device for controlling the control current of at least one connected laser diode. With the second terminals, an integrated device for suppressing current and/or voltage transients is provided, which is expediently also connected to at least one of the first terminals. In this way, the path between the first and second terminals, i.e., the path between a connected supply voltage and a connected laser diode, is protected against current and/or voltage transients.

What is important in this case is that the device for suppressing current and/or voltage transients is an integral part of the monolithic integrated circuit.

The subclaims relate to advantageous developments.

In order to prevent the laser diode from being damaged by voltage spikes during switch-off on account of the inductances contained in the lines, a recovery device is integrated in parallel with a connected laser diode in the monolithic integrated circuit, which device may be designed for example as a recovery diode connected antiparallel with respect to the laser diode, or as a transistor.

In order to prevent excessively high currents from being caused for example by damage to the laser diode or by interruption of the controlling device, a first detector is implemented in the monolithic integrated circuit, which can detect the magnitude of the control current fed to a connected laser diode for controlling the light power. In particular, the first detector detects the state when the control current exceeds a predetermined current value.

A second integrated detector is implemented in the monolithic integrated circuit in order to be able to detect overtemperatures within the circuit.

The protection of the laser diode against excessively high currents and excessively high temperatures is effected by means of an integrated switching device which, responding to the output signals of the first and/or second detector, limits the control current fed for controlling the light power of the laser diode to a predetermined value. The predetermined value is preferably 0 Amperes, so that, from the point of view of the laser diode, there is apparently no longer a connection to the supply voltage.

In order to prevent the limited control current from automatically rising again, the switching device is assigned a storage device which stores predetermined states, represented by the output signals of the first and/or second detector, in order to keep the switching device activated. As long as the switching device is activated, the control current is held at the predetermined value.

The switching device is deactivated only after a renewed application of the supply voltage to the second terminals, as a result of which the content of the storage device is cleared. At this instance, a control current again flows through the laser diode.

The storage device is preferably an RS flip-flop.

The object formulated above is likewise achieved by means of the features of the coordinate claim 9.

Accordingly, a monolithic integrated circuit for controlling the light power of a laser diode optically coupled to at least one photodiode is provided. Terminals for connecting at least one laser diode and for connecting the photodiode optically coupled to the laser diode are again provided. Furthermore, an integrated device for controlling the control current of at least one connected laser diode is implemented in the monolithic integrated circuit. A supply voltage can be applied to second terminals of the monolithic integrated circuit. In order to prevent an excessively high control current from flowing, signals which influence the magnitude of the control current are monitored. Responding to the deviation of at least one monitored signal from a predetermined desired value, a switching device implemented in the monolithic integrated circuit limits the control current fed for controlling the light power of the laser diode to a predetermined value, which is preferably 0 Amperes.

Furthermore, a first integrated detector is provided for monitoring a first signal which indicates that a predetermined magnitude of the control current fed to a connected laser diode for controlling the light power has been exceeded. A second integrated detector serves for monitoring a second signal which indicates that a predetermined temperature within the circuit has been exceeded.

Expediently, within the monolithic integrated circuit, the switching device is assigned a storage device for storing at least one state, represented by the at least one monitored signal, in order to keep the switching device activated. As long as the switching device is activated, the control current is held at the predetermined value.

The switching device is deactivated responding to a renewed application of a supply voltage to the second terminals, as a result of which the content of the storage device is cleared and the limiting of the control current is canceled.

The integrated device for controlling the control current of a connected laser diode contains a differentiating element, whose first input is provided for connection to a photodiode, whose second input may be connected to an internal reference voltage source and whose output is connected to the input of an integrated power driver which supplies the controlled control current for controlling the light power of a connected laser diode.

The invention is explained in more detail below using an exemplary embodiment in conjunction with the accompanying FIGURE.

The FIGURE shows a monolithic integrated circuit which is designed as a driver for a laser diode and is generally designated by 10. The monolithic integrated circuit 10, referred to below as laser diode driver, has terminals 20 and 22, to which a supply voltage source can be connected (not illustrated), which may supply for example a DC voltage of 2.4 to 6 volts. The capacitor 30 connected to the terminal 20 serves for smoothing the supply voltage. The laser diode driver 10 has five further terminals 40, 42, 44, 46, 48, to which a laser diode 50 and a photodiode 60 optically coupled to the laser diode can be connected. In this case, by way of example, the cathode of the photodiode 60 and the anode of the laser diode 50 are connected to the terminal 40. The anode of the photodiode 60 is connected to the terminal 42 of the integrated laser diode driver 10. The anode of the photodiode 60 is furthermore connected to the terminal 48 via a resistor 70. As will be explained in more detail below, the resistor 70, whose value may lie between 0.2 and 50 kilo-ohms, serves for the definition of the desired current of the photodiode 60. In this exemplary embodiment, the cathode of the laser diode 50 is connected to the terminal 46 of the laser diode driver. In order to stabilize the control loop implemented in the laser diode driver 10 and in order to determine the time constant of the control loop, a capacitor 80 is connected between the terminals 44 and 48. As is furthermore shown in the FIGURE, the terminal 22 is grounded.

In order to control the control current for the laser diode 50, a differentiating element 90 is integrated in the laser diode driver 10, whose inverting input is connected to the terminal 42 and thus to the anode of the photodiode 60. The noninverting input of the differentiating element 90 is connected to a reference voltage source 95, which supplies for example a DC voltage of 0.5 volt. The output of the differentiating element 90 is connected to the input of a power driver 100, which, in the present example, comprises an npn preliminary transistor 105 and an npn main transistor 107. In this case, the output of the differentiating element 90 is connected to the base of the preliminary transistor 105. The collector of the preliminary transistor 105 is furthermore connected to the terminals 40. A switching device 110 is connected to the base of the preliminary transistor 105, which switching device is only illustrated diagrammatically and the function of which switching device will be explained in more detail further below. The emitter of the preliminary transistor 105 is connected to the base of the main transistor 107. The collector of the main transistor 107 is connected to the terminals 46 and thus to the cathode of the laser diode 50 for supplying the control current. The collector of the main transistor 107 is furthermore connected to the terminals 40 via a recovery device 120. In the present example, the recovery device is implemented by a diode 120 connected antiparallel with respect to the laser diode 50. The recovery diode serves as transient protection for the laser diode 50, in order, at the switch-off instant, to be able to dissipate the energy stored in the line inductances via the recovery diode, and thus to keep voltage spikes away from the laser diode 50. The emitter of the main transistor 107 is connected to the input of a current detector 145, which monitors the control current to the laser diode 50. The current detector 145 is connected firstly to the terminals 22 and secondly to the R input of a storage device 130, which is designed as an RS flip-flop in this example. Furthermore, a temperature detector 140 is integrated in the laser diode driver 10, whose output is connected to a further R input of the RS flip-flop 130. The S input of the RS flip-flop 130 is connected to the collector of the preliminary transistor 105. Connected between the terminals 20 and the terminals 40 is a device 150 for suppressing current and/or voltage transients which are coupled into the laser diode driver 10 via the voltage supply device or other interference sources. The suppression device 150 comprises, for example, two zener diodes 152 which are connected in parallel to one another and whose cathodes are isolated by a resistor 154. The anode terminals of the zener diodes 152 are connected for example to a free star point. As a result of these connections, both the suppression device 150 and the recovery diode 120 function as an inversen polarity reversal protection for the laser diode driver 10. This means that if a supply voltage source is inadvertently connected to the terminals 22 by the positive pole, no appreciable current flows to the laser diode 50.

The method of operation of the laser diode driver 10 is explained in more detail below.

In the normal undisturbed operating state, the switching device 110 connected to the storage device 130 is open. Accordingly, an electrical potential is applied to the base of the preliminary transistor 105 via the output of the differentiating element 90, which potential drives the preliminary transistor 105 and the main transistor 107, so that the main transistor 107 turns on. In this state, in a manner caused by the applied supply voltage, a current flows via the terminal 20, the terminal 40, the laser diode 50, the terminal 46, the collector-emitter path of the main transistor 107 and the current detector 120 to the terminals 22, which is grounded. The light power of the laser diode 50 is controlled with the aid of the photodiode 60, which converts the light emitted by the laser diode 50 into a photocurrent whose maximum value is defined by the resistor 70 and the reference voltage 95. The control loop is basically formed by the differentiating element 90, the reference voltage source 95, the power driver 100, the photodiode 60 and the laser diode 50. The current generated by the photodiode 60 leads to a voltage drop across the resistor 70, said voltage drop being applied to the inverting input of the differentiating element 90. This electrical potential is compared with the DC voltage provided by the reference source 95, in the present case 0.5 V, which is present at the noninverting input of the differentiating element. In this way, the voltage potential present at the terminals 42 is controlled to 0.5 volt. If the voltage potential at the terminal 42 exceeds 0.5 volt, the differentiating element 90 reduces, via its output, the potential at the base of the preliminary transistor 105, as result of which the main transistor 107 attains higher impedance and the control current to the laser diode 50, which controls the light power, is reduced. As long as the potential at the terminals 42 is less than 0.5 volt, the differentiating element 90 increases the voltage potential at the base of the preliminary transistor 105, as a result of which the collector-emitter path of the main transistor 107 attains lower impedance, and a higher control current flows through the laser diode; as a result, the light power is also increased. Voltage and/or current transients that occur, which are coupled in via the terminal 20, are kept away from the laser diode 50 by the device 150 for suppressing current and/or voltage transients.

Up to this point, the normal, disturbance-free operation of the laser diode driver 10 has been explained. Two disturbance situations to which the driver 10 can react will now be described.

In accordance with a first scenario, suppose that the temperature detector 140 determines that a predetermined operating temperature of the laser diode driver 10 has been exceeded. The RS flip-flop 130 is thereupon set by means of the output signal of the temperature detector 140. Responding thereto, the switching device 110 is activated, i.e., the symbolically illustrated switch is closed. Since the switch is directly grounded in the present example, the potential at the base of the preliminary transistor 105 is pulled to 0 volts, as result of which the main transistor 107 attains high impedance, so that a control current no longer flows through the laser diode 50. In other words, the control current through the laser diode 50 is limited to 0 Amperes. However, if the switching device 110 is connected, for example, to the base of the preliminary transistor 105 via a diode (not illustrated), the control current can be limited to the predetermined value greater than 0 Amperes. The switching device 110 remains activated, i.e., the switch is closed, as long as the RS flip-flop 130 remains set. As soon as the supply voltage, previously disconnected from the laser diode driver 10, is applied anew to the terminals 20 and 22, this state is communicated to the RS flip-flop 130 via the S input. The RS flip-flop 130 is thus reset and the switching device 110 is deactivated, i.e., the switch is opened again. At this instant, the laser diode driver 10 is in normal operation again, and the light power of the laser diode 50 can be controlled by means of the control loop.

The turn-off procedure of the laser diode driver 10 triggered by the temperature detector 140 also proceeds when the current detector 145 measures a control current through the laser diode 50 which exceeds a predetermined current value. In this case, too, the fact that the current value has been exceeded is signaled to the R input of the RS flip-flop 130, whereupon the switching device 110 is activated, i.e., the switch is opened. The RS flip-flop 130 is again reset by renewed application of the supply voltage source that was previously turned off.

Reference Symbols

10 monolithic integrated laser diode driver

20,22 terminals

30 capacitor

40-48 terminals

50 laser diode

60 photodiode

70 resistor

80 capacitor

90 differentiating element

95 reference voltage source

100 power driver

105 preliminary transistor

107 main transistor

110 switching device

120 recovery diode

130 storage device, RS flip-flop

140 temperature detector

145 current detector

150 transient protection device

152 zener diodes

154 resistor

1. A monolithic integrated circuit (10) for controlling the light power of a laser diode (50) optically coupled to at least one photodiode (60), having
first terminals (40, 42, 44, 46, 48) for connecting at least one laser diode (50) and for connecting at least one photodiode (60) optically coupled thereto,
an integrated device (90, 100) for controlling the control current of at least one connected laser diode (50),
second terminals (20, 22) for applying a supply voltage, and having an integrated device (150) connected to the second terminals and serving to suppress current and/or voltage transients.

2. The monolithic integrated circuit as claimed in claim 1, which has an integrated recovery device (120), which is connected antiparallel with respect to a connected laser diode (50).

3. The monolithic integrated circuit as claimed in claim 1 or 2; which has a first integrated detector (145) for detecting the magnitude of the control current fed to a connected laser diode (50) for controlling the light power.

4. The monolithic integrated circuit as claimed in one of claims 1 to 3, which has a second integrated detector (140) for detecting the temperature within the circuit.

5. The monolithic integrated circuit as claimed in claim 3 or 4, which has an integrated switching device (110), which, responding to the output signals of the first and/or second detector (140, 145), limits the control current fed for controlling the light power of the laser diode (50) to a predetermined value.

6. The monolithic integrated circuit as claimed in claim 5, which has a storage device (130) assigned to the switching device (110) and serving to store predetermined states, represented by the output signals of the first and/or second detector, in order to permanently activate the switching device for limiting the control current to the predetermined value.

7. The monolithic integrated circuit as claimed in claim 6, wherein,
responding to a renewed application of the supply voltage to the second terminals (20, 22), the content of the storage device (130) is cleared in order to deactivate the switching device (110).

8. The monolithic integrated circuit as claimed in claim 6 or 7, wherein the storage device (130) is an RS flip-flop.

9. A monolithic integrated circuit (10) for controlling the light power of a laser diode (50) optically coupled to at least one photodiode (60), having
first terminals (40, 42, 44, 46, 48) for connecting at least one laser diode and for connecting at least one photodiode (60) optically coupled thereto,
an integrated device (90, 100) for controlling the control current of at least one connected laser diode (50),
second terminals (20, 22) for applying a supply voltage, and having an integrated switching device (110), which, responding to the deviation of at least one monitored signal from a predetermined desired value, limits the control current fed for controlling the light power of the laser diode (50) to a predetermined value.

10. The monolithic integrated circuit as claimed in claim 9, which has a first integrated detector (145) for monitoring a first signal which indicates that a predetermined magnitude of the control current fed to a connected laser diode (50) for controlling the light power has been exceeded.

11. The monolithic integrated circuit as claimed in claim 9 or 10, which has a second integrated detector (140) for monitoring a second signal which indicates that a predetermined temperature within the circuit has been exceeded.

12. The monolithic integrated circuit as claimed in one of claims 9 to 11, which has a storage device (130) assigned to the switching device (110) and serving to store at least one state, represented by the at least one monitored signal, in order to permanently activate the switching device (110) for limiting the control current to the predetermined value.

13. The monolithic integrated circuit as claimed in claim 12, wherein, responding to a renewed application of a supply voltage to the second terminals (20, 22), the content of the storage device (130) is cleared in order to deactivate the switching device (110).

14. The monolithic integrated circuit as claimed in claim 12 or 13, wherein the storage device (130) is an RS flip-flop.

15. The monolithic integrated circuit as claimed in one of claims 1 to 14, wherein the integrated device for controlling the control current of at least one connected laser diode (50) contains a differential amplifier (90), whose first input is provided for connection to a photodiode (60), whose second input is connected to a reference voltage source (95) and whose output is connected to the input of a power driver (100) which supplies the controlled control current for controlling the light power of a connected laser diode (50).
